(19) United States
(12) Patent Application Publication
(10) Pub. No.: US 2017/0328942 A1
(43) Pub. Date: Nov. 16, 2017

(54) ELECTROSTATIC SCANNER HAVING SENSING COMB ASSEMBLIES

(71) Applicant: Ultimems, Inc., New Taipei City (TW)

(72) Inventors: Yee-Chung Fu, Fremont, CA (US); Han-Tang Su, Taichung City (TW)

(73) Assignee: Ultimems, Inc., New Taipei City (TW)

(21) Appl. No.: 15/489,752

(22) Filed: Apr. 18, 2017

Related U.S. Application Data
(60) Provisional application No. 62/333,846, filed on May 10, 2016.

(51) Int. Cl. G01R 29/12

(52) U.S. Cl. CPC G01R 29/12

(57) ABSTRACT

An electrostatic scanner is disclosed. The electrostatic scanner comprises a mirror, one or more actuating comb assemblies, one or more sensing comb assemblies and two or more springs. The one or more sensing comb assemblies each have a movable sensing combteeth set, an upper fixed sensing combteeth set and a lower fixed sensing combteeth set. The upper fixed sensing combteeth set and the movable sensing combteeth set form an in-plane comb configuration. The lower fixed sensing combteeth set and the movable sensing combteeth set form a vertical comb configuration. An upper fixed sensing combtooth of the upper fixed sensing combteeth set is shorter than a lower fixed sensing combtooth of the lower fixed sensing combteeth set.

### CROSS-REFERENCE TO RELATED APPLICATIONS

This patent application claims benefit of a provisional patent application 62/333,846. The disclosure made in the provisional patent application 62/333,846 is hereby incorporated by reference. U.S. Pat. No. 7,014,115 to Fu, U.S. Pat. No. 7,538,927 to Fu and U.S. Pat. No. 9,201,239 to Fu are hereby incorporated by reference.

### FIELD OF THE INVENTION

This invention relates generally to an electrostatic scanner. More particularly, the present invention relates to a Micro-Electro Mechanical Systems (MEMS) electrostatic scanner having sensing comb assemblies.

### BACKGROUND OF THE INVENTION

U.S. Pat. No. 7,014,115 to Fu discloses a MEMS scanning mirror with distributed hinges and multiple support attachments. FIG. 1A, 1B, 1C, 2, 3, and 4 of U.S. Pat. No. 7,538,927 to Fu discloses a process to construct a scanning mirror with short vertical combteeth in a vertical comb drive and long in-plane combteeth in an in-plane comb drive. U.S. Pat. No. 9,201,239 to Fu discloses a two-dimensional electrostatic scanner with distributed springs. This invention discloses an electrostatic scanner having sensing comb assemblies. One of the advantages of the present invention is that angular positions of the mirror can be determined by measuring the capacitance from the sensing comb assemblies. The determined angular positions of the mirror can be used for feedback control.

### SUMMARY OF THE INVENTION

This invention discloses an electrostatic scanner comprising a mirror, one or more actuating comb assemblies, one or more sensing comb assemblies and two or more springs. The one or more sensing comb assemblies each have a movable sensing combteeth set, an upper fixed sensing combteeth set and a lower fixed sensing combteeth set. The upper fixed sensing combteeth set and the movable sensing combteeth set form an in-plane comb configuration. The lower fixed sensing combteeth set and the movable sensing combteeth set form a vertical comb configuration. An upper fixed sensing combtooth of the upper fixed sensing combteeth set is shorter than a lower fixed sensing combtooth of the lower fixed sensing combteeth set.

### BRIEF DESCRIPTION OF THE DRAWINGS

FIG. 1 is a schematic perspective view of an electrostatic scanner in examples of the present disclosure.

FIG. 2 is a top view of an upper layer of the electrostatic scanner of FIG. 1 in examples of the present disclosure.

FIG. 3 is a top view of a lower layer of the electrostatic scanner of FIG. 1 in examples of the present disclosure.

FIG. 4 is a top view of a portion of a sensing comb assembly of the electrostatic scanner of FIG. 1 in examples of the present disclosure.

FIG. 5 shows a capacitance versus angle curve of a sensing comb assembly in examples of the present disclosure.

FIG. 6 shows a derivative of capacitance with respect to angle versus angle curve of a sensing comb assembly in examples of the present disclosure.

FIG. 7 is a schematic perspective view of an electrostatic scanner in examples of the present disclosure.

FIG. 8 is a schematic perspective view of a two-dimensional electrostatic scanner in examples of the present disclosure.

FIG. 9 is a schematic perspective view of an electrostatic scanner in examples of the present disclosure.

FIG. 10 is a cross-sectional view of through silicon vias.

FIG. 11 is a cross-sectional view of through silicon vias.

FIG. 12 is a cross-sectional view of eutectic bonded electrodes.

FIG. 13 is a schematic perspective view of an electrostatic scanner in examples of the present disclosure.

### DETAILED DESCRIPTION OF THE INVENTION

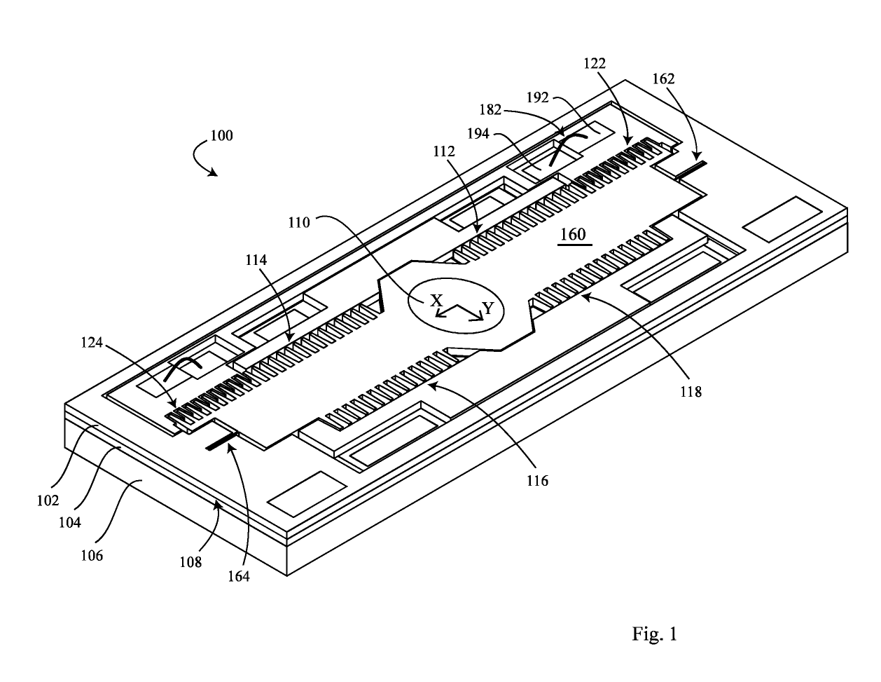

FIG. 1 is a schematic perspective view of an electrostatic scanner 100 in examples of the present disclosure. The electrostatic scanner 100 comprises an upper layer 102, a lower layer 104, and a base 106. The upper layer 102 is higher than the lower layer 104. The lower layer 104 is higher than the base 106. In examples of the present disclosure, the upper layer 102 and the lower layer 104 is separated by an insulation layer 108. The electrostatic scanner 100 includes a mirror 110, four vertically actuating comb assemblies 112, 114, 116 and 118, two sensing comb assemblies 122 and 124, a frame 160, and two springs 162 and 164. The mirror rotates about X-axis. Combteeth of the four vertically actuating comb assemblies 112, 114, 116 and 118 and combteeth of the two sensing comb assemblies 122 and 124 extend parallel to Y-axis.

The two springs 162 and 164 rotate about the X-axis. The two springs 162 and 164 are symmetric with respect to the Y-axis.

In examples of the present disclosure, the four vertically actuating comb assemblies 112, 114, 116 and 118 are symmetric with respect to the X-axis and are symmetric with respect to the Y-axis. In examples of the present disclosure, the two sensing comb assemblies 122 and 124 are asymmetric with respect to the X-axis and are symmetric with respect to the Y-axis. To reduce the added inertia of the moving part of the electrostatic scanner 100, no sensing comb assemblies are located at Y>0.

In examples of the present disclosure, the electrostatic scanner 100 further includes a plurality of upper pads (for example, upper pad 192) and a plurality of lower pads (for example, lower pad 194). In examples of the present disclosure, a wire 182 mechanically connects the upper pad 192 to the lower pad 194.

In examples of the present disclosure, the upper layer 102 and the lower layer 104 are made of a silicon material. The base 106 is made of a glass material. The insulation layer 108 is made of a silicon dioxide material.

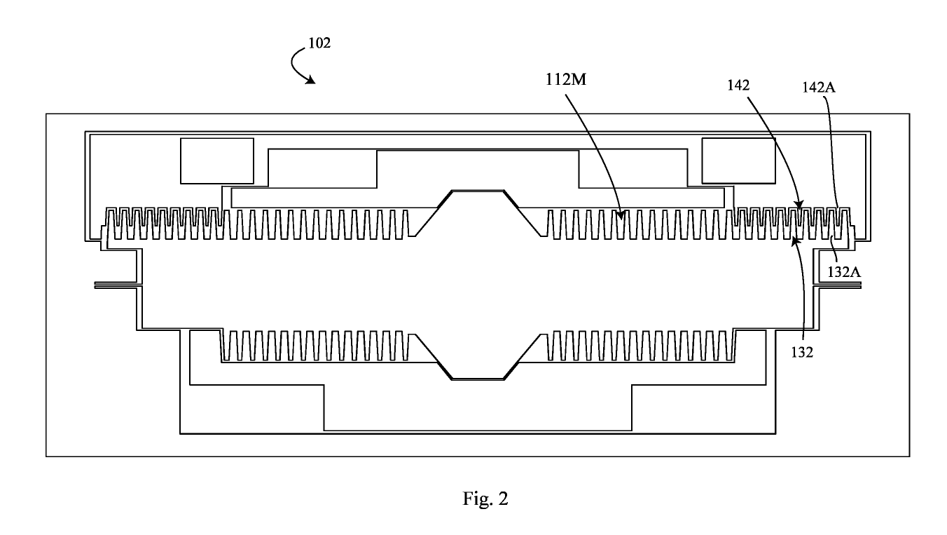

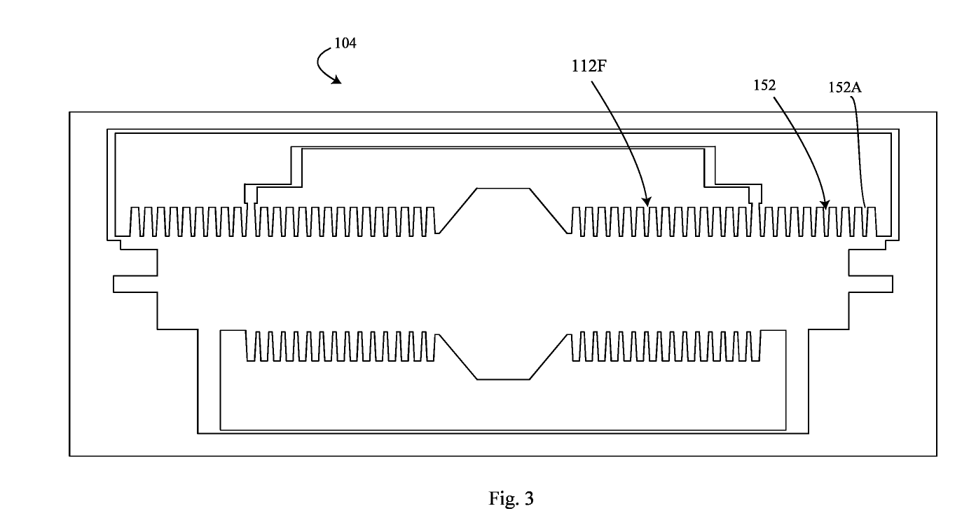

FIG. 2 is a top view of the upper layer 102 of the electrostatic scanner 100 of FIG. 1 in examples of the present disclosure. FIG. 3 is a top view of the lower layer 104 of the electrostatic scanner 100 of FIG. 1 in examples of the present disclosure. The vertically actuating comb assembly 112 of FIG. 1 comprises a movable actuating combteeth set 112M of FIG. 2 and a fixed actuating combteeth set 112F of FIG. 3. The movable actuating combteeth set 112M rotates about the X-axis. Viewing along Z-axis, the movable actuating combteeth set 112M and the fixed actuating combteeth set 112F are interdigitated.

The sensing comb assembly 122 of FIG. 1 comprises a movable sensing combteeth set 132 of FIG. 2, an upper fixed sensing combteeth set 142 of FIG. 2 and a lower fixed sensing combteeth set 152 of FIG. 3. In examples of the present disclosure, the upper fixed sensing combteeth set 142 and the movable sensing combteeth set 132 are made from the upper layer 102. Therefore, the upper fixed sensing combteeth set 142 and the movable sensing combteeth set 132 form an in-plane comb configuration. In examples of the present disclosure, the movable sensing combteeth set 132 is made from the upper layer 102 and the lower fixed sensing combteeth set 152 is made from the lower layer 104. Therefore, the lower fixed sensing combteeth set 152 and the movable sensing combteeth set 132 form a vertical comb configuration. The movable sensing combteeth set 132 rotates about the X-axis. The movable sensing combteeth set 132 and the upper fixed sensing combteeth set 142 are interdigitated. Viewing along Z-axis, the movable sensing combteeth set 132 and the lower fixed sensing combteeth set 152 are interdigitated.

In examples of the present disclosure, the upper fixed sensing combteeth set 142 is electrically connected to the upper pad 192 of FIG. 1 and the lower fixed sensing combteeth set 152 is electrically connected to the lower pad 194 of FIG. 1.

In examples of the present disclosure, the movable actuating combteeth set 112M and the movable sensing combteeth set 132 extend away from the frame 160 of FIG. 1. In examples of the present disclosure, combteeth of the movable actuating combteeth set 112M and combteeth of the movable sensing combteeth set 132 have a same length. In examples of the present disclosure, combteeth of the movable actuating combteeth set 112M, combteeth of the fixed actuating combteeth set 112F, combteeth of the movable sensing combteeth set 132, combteeth of the upper fixed sensing combteeth set 142 and combteeth of the lower fixed sensing combteeth set 152 are of tapered shapes.

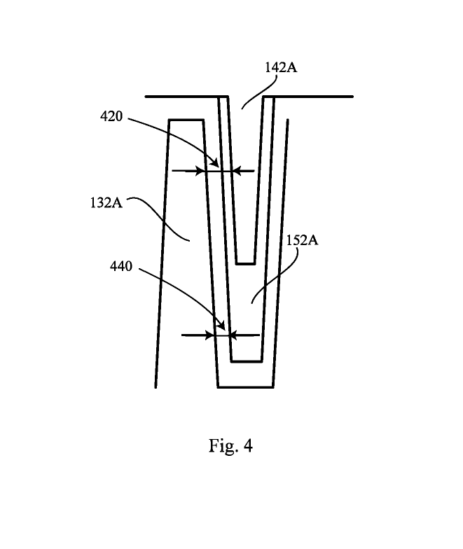

FIG. 4 is a top view of a movable sensing combtooth 132A of the movable sensing combteeth set 132 of FIG. 2, an upper fixed sensing combtooth 142A of the upper fixed sensing combteeth set 142 of FIG. 2 and a lower fixed sensing combtooth 152A of the lower fixed sensing combteeth set 152 of FIG. 3. During an electrostatic scanner resting state, the movable sensing combtooth 132A is at a same height as the upper fixed sensing combtooth 142A. During an electrostatic scanner resting state, the movable sensing combtooth 132A is located at a position higher than the lower fixed sensing combtooth 152A.

In examples of the present disclosure, the upper fixed sensing combtooth 142A is shorter than the lower fixed sensing combtooth 152A. A gap 420 in the X-direction between the movable sensing combtooth 132A and the upper fixed sensing combtooth 142A is larger than a gap 440 in the X-direction between the movable sensing combtooth 132A and the lower fixed sensing combtooth 152A.

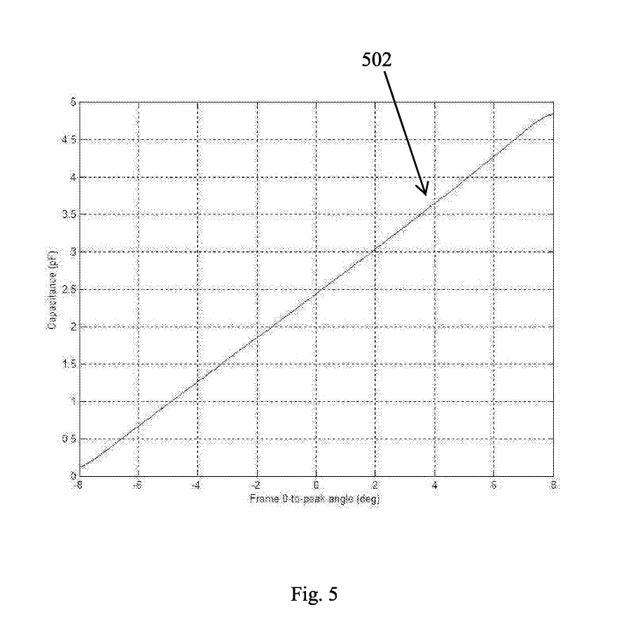

FIG. 5 shows a capacitance versus angle curve 502 of a sensing comb assembly in examples of the present disclosure. From −8 degrees to 7 degrees, the curve 502 has a substantially constant slope. The angular position of the mirror 110 can be determined by the measured capacitance.

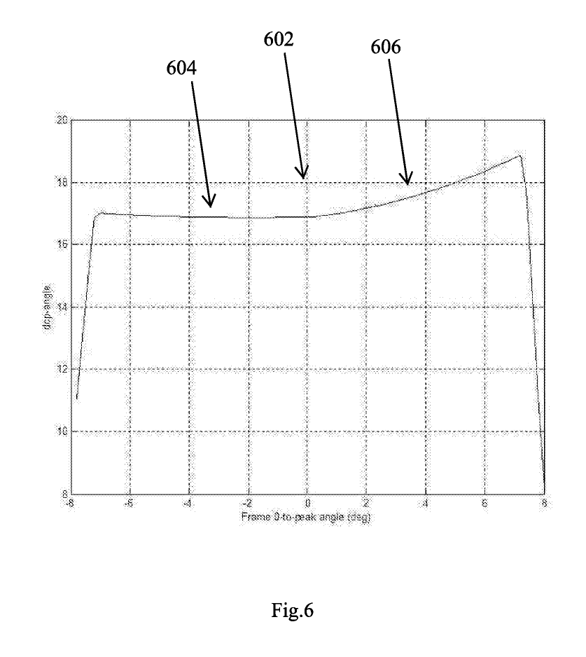

FIG. 6 shows a derivative of capacitance with respect to angle versus angle curve 602 of a sensing comb assembly in examples of the present disclosure. Zero-degree angle corresponds to a resting state of the electrostatic scanner. A positive angle corresponds to engaging of the movable sensing combteeth set 132 of FIG. 2 and the lower fixed sensing combteeth set 152 of FIG. 3. A negative angle corresponds to a condition that a top surface of the movable sensing combteeth set 132 of FIG. 2 is at a position higher than a top surface of the upper fixed sensing combteeth set 142 of FIG. 2. Curve 602 has a substantially flat portion 604 and a sloped portion 606. Portion 604 corresponds to an in-plane comb configuration. Portion 606 corresponds to a vertical comb configuration with minor contribution from the in-plane comb configuration.

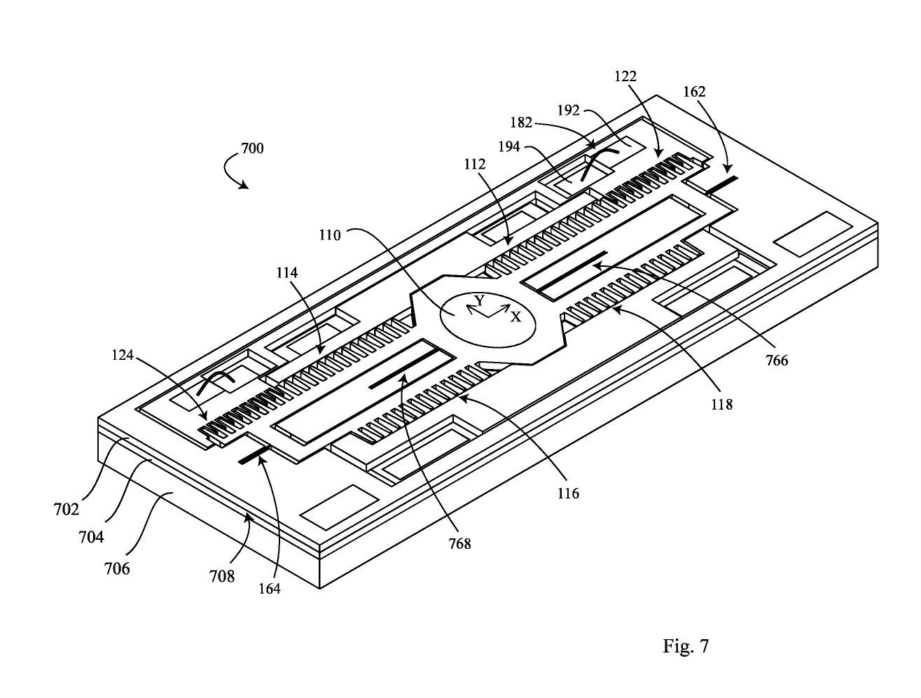

FIG. 7 is a schematic perspective view of an electrostatic scanner 700 in examples of the present disclosure. The electrostatic scanner 700 comprises an upper layer 702, a lower layer 704, and a base 706. In examples of the present disclosure, the upper layer 702 and the lower layer 704 is separated by an insulation layer 708. The electrostatic scanner 700 includes a mirror 110, four vertically actuating comb assemblies 112, 114, 116 and 118, two sensing comb assemblies 122 and 124, and four springs 162, 164, 766 and 768. The mirror rotates about X-axis. Combteeth of the four vertically actuating comb assemblies 112, 114, 116 and 118 and combteeth of the two sensing comb assemblies 122 and 124 extend parallel to Y-axis.

In examples of the present disclosure, the electrostatic scanner 700 further includes a plurality of upper pads (for example, upper pad 192) and a plurality of lower pads (for example, lower pad 194). In examples of the present disclosure, a wire 182 mechanically and electrically connects the upper pad 192 to the lower pad 194.

The four springs 162, 164, 766 and 768 rotate about the X-axis. The four springs 162, 164, 766 and 768 are symmetric with respect to the Y-axis. The spring 766 is between the mirror 110 and the spring 162. The spring 768 is between the mirror 110 and the spring 164.

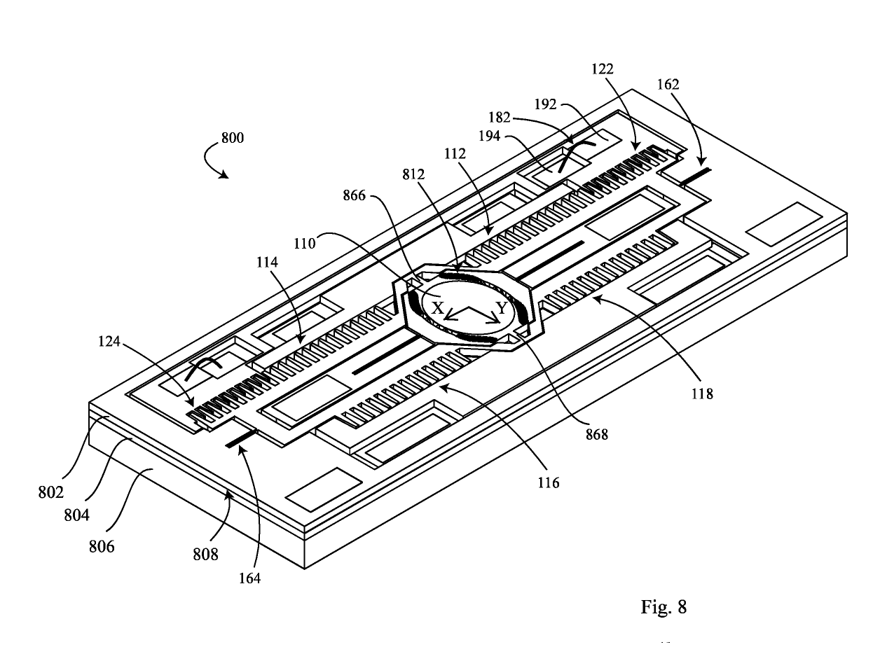

FIG. 8 is a schematic perspective view of an electrostatic scanner 800 in examples of the present disclosure. The electrostatic scanner 800 comprises an upper layer 802, a lower layer 804, and a base 806. In examples of the present disclosure, the upper layer 802 and the lower layer 804 is separated by an insulation layer 808. The electrostatic scanner 800 includes a mirror 110, four vertically actuating comb assemblies 112, 114, 116 and 118, two sensing comb assemblies 122 and 124, one or more in-plane actuating comb assemblies 812, two or more X-directional springs 162 and 164, and two Y-directional springs 866 and 868. The mirror rotates about X-axis. Combteeth of the four vertically actuating comb assemblies 112, 114, 116 and 118 and combteeth of the two sensing comb assemblies 122 and 124 extend parallel to Y-axis.

In examples of the present disclosure, the electrostatic scanner 800 further includes a plurality of upper pads (for example, upper pad 192) and a plurality of lower pads (for example, lower pad 194). In examples of the present disclosure, a wire 182 mechanically connects the upper pad 192 to the lower pad 194.

The two Y-directional springs 866 and 868 rotate about the Y-axis. The two Y-directional springs 866 and 868 are symmetric with respect to the X-axis.

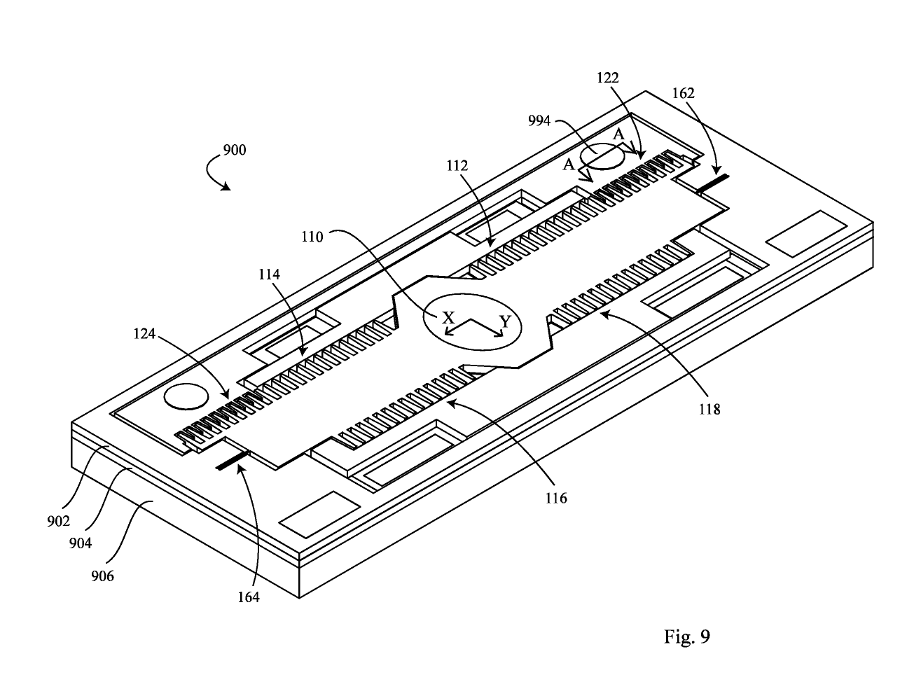

FIG. 9 is a schematic perspective view of an electrostatic scanner 900 in examples of the present disclosure. The electrostatic scanner 900 comprises an upper layer 902, a lower layer 904, and a base 906. The electrostatic scanner 900 includes a mirror 110, four vertically actuating comb assemblies 112, 114, 116 and 118, two sensing comb assemblies 122 and 124, and two springs 162 and 164. The mirror rotates about X-axis. Combteeth of the four vertically actuating comb assemblies 112, 114, 116 and 118 and combteeth of the two sensing comb assemblies 122 and 124 extend parallel to Y-axis.

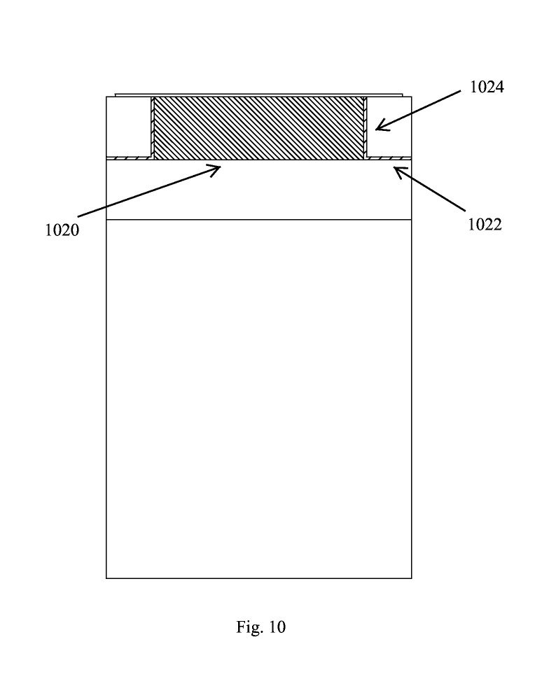

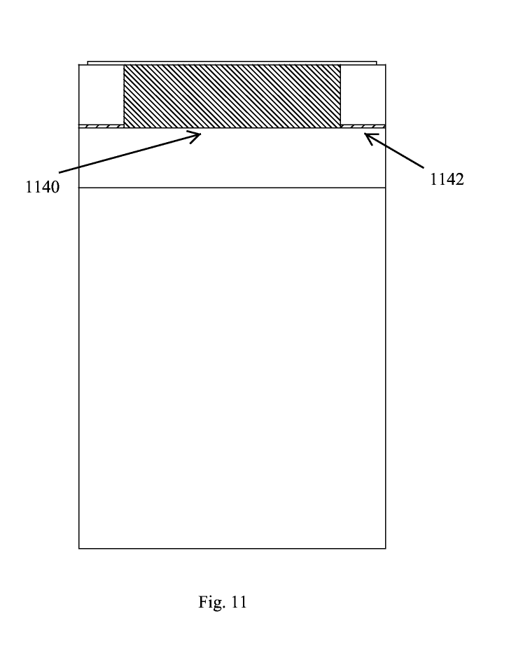

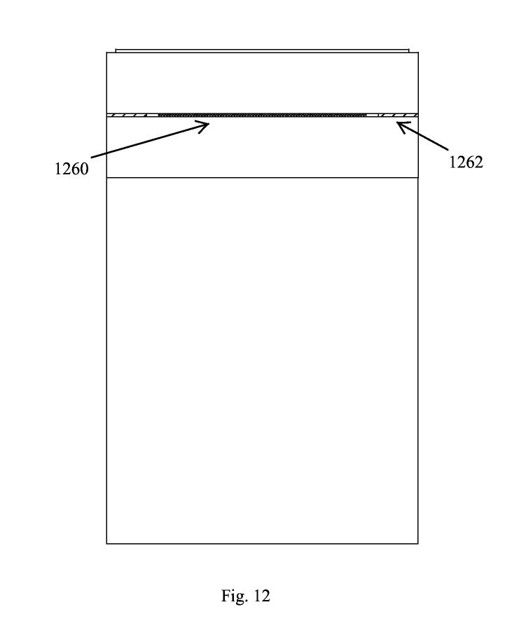

FIGS. 10-12 are examples of cross-sections along AA of FIG. 9. In examples of the present disclosure, the electrostatic scanner 900 further includes a region 944 having through silicon vias or having eutectic bonded electrodes. In one example, the upper fixed sensing combteeth set 142 of FIG. 2 and the lower fixed sensing combteeth set 152 of FIG. 3 are electrically and mechanically connected by through silicon via 1020 of FIG. 10 or through silicon via 1140 of FIG. 11. The through silicon via 1020 of FIG. 10 is between horizontal insulation 1022 and vertical insulation 1024. The through silicon via 1140 of FIG. 11 is between horizontal insulation 1142. In another example, the upper fixed sensing combteeth set 142 of FIG. 2 is connected to an upper electrode. The lower fixed sensing combteeth set 152 of FIG. 3 is connected to a lower electrode. The upper and lower electrodes are eutectically bonded to form eutectic bonded electrodes 1260 of FIG. 12. The eutectic bonded electrodes 1260 of FIG. 12 are between horizontal insulation 1262.

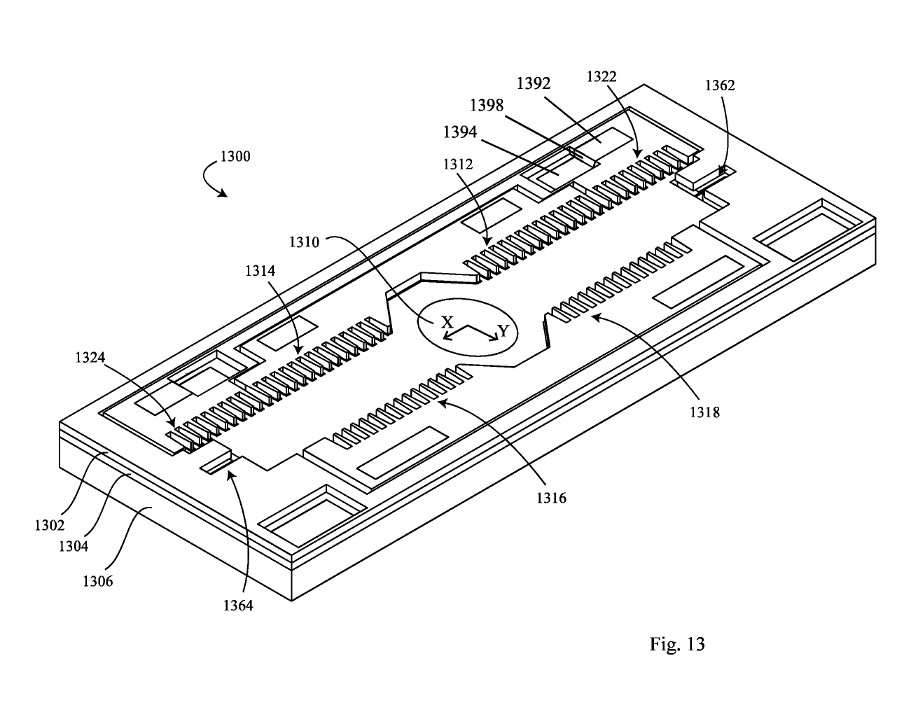

FIG. 13 is a schematic perspective view of an electrostatic scanner 1300 in examples of the present disclosure. The electrostatic scanner 1300 comprises an upper layer 1302, a lower layer 1304, and a base 1306. The electrostatic scanner 1300 includes a mirror 1310, four vertically actuating comb assemblies 1312, 1314, 1316 and 1318, two sensing comb assemblies 1322 and 1324, and two springs 1362 and 1364. The mirror rotates about X-axis. Combteeth of the four vertically actuating comb assemblies 1312, 1314, 1316 and 1318 and combteeth of the two sensing comb assemblies 1322 and 1324 extend parallel to Y-axis.

The electrostatic scanner 1300 is similar to the electrostatic scanner 100 of FIG. 1 except that movable parts of the electrostatic scanner 1300 are in the lower layer 1304. The lower layer 1304 includes the mirror 1310, a movable actuating combteeth set of the vertically actuating comb assembly 1312, a movable sensing combteeth set of the sensing comb assembly 1322, and a lower fixed sensing combteeth set of the sensing comb assembly 1322. The upper layer 1302 includes an upper fixed sensing combteeth set of the sensing comb assembly 1322. The upper fixed sensing combteeth set of the sensing comb assembly 1322 and the movable sensing combteeth set of the sensing comb assembly 1322 form a vertical comb configuration. The lower fixed sensing combteeth set of the sensing comb assembly 1322 and the movable sensing combteeth set of the sensing comb assembly 1322 form an in-plane comb configuration.

In examples of the present disclosure, the electrostatic scanner 1300 further includes a plurality of upper pads (for example, upper pad 1392) and a plurality of lower pads (for example, lower pad 1394). A connecting pad 1398 mechanically connects the upper pad 1392 to the lower pad 1394. The connecting pad 1398 is directly attached to the vertical wall between the upper pad 1392 and the lower pad 1394. In one example, the connecting pad 1398 is deposited onto the vertical wall by vapor deposition. In examples of the present disclosure, the upper fixed sensing combteeth set of the sensing comb assembly 1322 is electrically connected to the upper pad 1392 and the lower fixed sensing combteeth set of the sensing comb assembly 1322 is electrically connected to the lower pad 1394.

Those of ordinary skill in the art may recognize that modifications of the embodiments disclosed herein are possible. For example, the number of vertically actuating comb assemblies may vary; the number of springs may vary; and the shape and the size of the mirror may vary. Other modifications may occur to those of ordinary skill in this art, and all such modifications are deemed to fall within the purview of the present invention, as defined by the claims.

1. An electrostatic scanner comprising:
a mirror to rotate about a first direction;
one or more vertically actuating comb assemblies including:
a first vertically actuating comb assembly containing:
a first movable actuating combteeth set to rotate about the first direction; and
a first fixed actuating combteeth set extending along a second direction perpendicular to the first direction; and
one or more sensing comb assemblies including:
a first sensing comb assembly containing:
a first movable sensing combteeth set to rotate about the first direction;
a first upper fixed sensing combteeth set extending along the second direction; and
a first lower fixed sensing combteeth set extending along the second direction;
wherein combteeth of the first upper fixed sensing combteeth set are shorter than combteeth of the first lower fixed sensing combteeth set;
wherein the first upper fixed sensing combteeth set and the first movable sensing combteeth set form an in-plane comb configuration; and
wherein the first lower fixed sensing combteeth set and the first movable sensing combteeth set form a vertical comb configuration.

2. The electrostatic scanner of claim 1, wherein the first upper fixed sensing combteeth set is electrically connected to a first upper pad;
wherein the first lower fixed sensing combteeth set is electrically connected to a first lower pad; and
wherein a wire mechanically and electrically connects the first upper pad to the first lower pad.

3. The electrostatic scanner of claim 1, wherein the first upper fixed sensing combteeth set is electrically connected to a first upper pad;
wherein the first lower fixed sensing combteeth set is electrically connected to a first lower pad;
wherein a connecting pad mechanically and electrically connects the first upper pad to the first lower pad; and
wherein the connecting pad is attached to a vertical wall between the first upper pad and the first lower pad.

4. The electrostatic scanner of claim 1, wherein the first upper fixed sensing combteeth set is electrically connected to a first upper electrode;
wherein the first lower fixed sensing combteeth set is electrically connected to a first lower electrode; and
through silicon vias mechanically and electrically connect the first upper electrode to the first lower electrode.

5. The electrostatic scanner of claim 1, wherein the first upper fixed sensing combteeth set is electrically connected to a first upper electrode;
wherein the first lower fixed sensing combteeth set is electrically connected to a first lower electrode; and
the first upper electrode and the first lower electrode are eutectically bonded.

6. The electrostatic scanner of claim 1 further comprising an insulation layer between the first upper fixed sensing combteeth set and the first lower fixed sensing combteeth set;
wherein the first upper fixed sensing combteeth set is directly attached to a top surface of the insulation layer; and
wherein the first lower fixed sensing combteeth set is directly attached to a bottom surface of the insulation layer.

7. The electrostatic scanner of claim 1 further comprising a base made of a glass material.

8. The electrostatic scanner of claim 1 further comprising a frame, wherein the first movable actuating combteeth set and the first movable sensing combteeth set extend away from the frame.

9. The electrostatic scanner of claim 8, wherein combteeth of the first movable actuating combteeth set and combteeth of the first movable sensing combteeth set have a same length.

10. The electrostatic scanner of claim 1, wherein a first gap in the first direction between a combtooth of the first movable sensing combteeth set and an adjacent upper combtooth of the first upper fixed sensing combteeth set is larger than a second gap in the first direction between the combtooth of the first movable sensing combteeth set and an adjacent lower combtooth of the first lower fixed sensing combteeth set.

11. The electrostatic scanner of claim 1, wherein combteeth of the first movable actuating combteeth set and the first fixed actuating combteeth set are of tapered shapes.

12. The electrostatic scanner of claim 1, wherein combteeth of the first movable sensing combteeth set, the first upper fixed sensing combteeth set and the first lower fixed sensing combteeth set are of tapered shapes.

13. The electrostatic scanner of claim 1, wherein the one or more vertically actuating comb assemblies are symmetric with respect to the first direction and are symmetric with respect to the second direction.

14. The electrostatic scanner of claim 1, wherein the one or more sensing comb assemblies are asymmetric with respect to the first direction and are symmetric with respect to the second direction.

15. The electrostatic scanner of claim 1 further comprising a first and second springs to rotate about the first direction, wherein the first and second springs are symmetric with respect to the second direction.

16. The electrostatic scanner of claim 15 further comprising a third and fourth springs to rotate about the first direction, wherein the third spring is between the mirror and the first spring; and
wherein the fourth spring is between the mirror and the second spring.

17. The electrostatic scanner of claim 15 further comprising a third and fourth springs to rotate about the second direction, wherein the third and fourth springs are symmetric with respect to the first direction.

18. An electrostatic scanner comprising:
a mirror to rotate about a first direction;
one or more vertically actuating comb assemblies including:
a first vertically actuating comb assembly containing:
a first movable actuating combteeth set to rotate about the first direction; and
a first fixed actuating combteeth set extending along a second direction perpendicular to the first direction; and
one or more sensing comb assemblies including:
a first sensing comb assembly containing:
a first movable sensing combteeth set to rotate about the first direction;
a first upper fixed sensing combteeth set extending along the second direction; and
a first lower fixed sensing combteeth set extending along the second direction;
wherein the first upper fixed sensing combteeth set and the first movable sensing combteeth set form an in-plane comb configuration;
wherein the first lower fixed sensing combteeth set and the first movable sensing combteeth set form a vertical comb configuration; and
wherein a first gap in the first direction between a combtooth of the first movable sensing combteeth set and an adjacent upper combtooth of the first upper fixed sensing combteeth set is larger than a second gap in the first direction between the combtooth of the first movable sensing combteeth set and an adjacent lower combtooth of the first lower fixed sensing combteeth set.

19. An electrostatic scanner comprising:
a mirror to rotate about a first direction;
one or more vertically actuating comb assemblies including:
a first vertically actuating comb assembly containing:
a first movable actuating combteeth set to rotate about the first direction; and
a first fixed actuating combteeth set extending along a second direction perpendicular to the first direction; and
one or more sensing comb assemblies including:
a first sensing comb assembly containing:
a first movable sensing combteeth set to rotate about the first direction;
a first upper fixed sensing combteeth set extending along the second direction; and
a first lower fixed sensing combteeth set extending along the second direction;
wherein the first upper fixed sensing combteeth set and the first movable sensing combteeth set form a vertical comb configuration; and
wherein the first lower fixed sensing combteeth set and the first movable sensing combteeth set form an in-plane comb configuration.
